(19) United States
(12) Patent Application Publication
(10) Pub. No.: US 2016/0008987 A1
(43) Pub. Date: Jan. 14, 2016

(54) PAD FOR TRANSFER APPARATUS, OBJECT TRANSFER APPARATUS INCLUDING THE PAD, AND OBJECT TRANSFER METHOD

(71) Applicant: Samsung Electronics Co., Ltd., Suwon-si (KR)

(72) Inventors: Won-Young Park, Chuncheongnam-do (KR); Jeong-Soo Kim, Chungcheongnam-do (KR)

(21) Appl. No.: 14/635,213

(22) Filed: Mar. 2, 2015

(30) Foreign Application Priority Data
Jul. 10, 2014 (KR) 10-2014-0086847

(51) Int. Cl. B25J 15/06; H01L 21/68; H01L 21/683

(52) U.S. Cl. CPC B25J 15/0616; H01L 21/6838; H01L 21/68; B25J 15/0658

(57) ABSTRACT

In a pad for a transfer apparatus, an object transfer apparatus, and an object transfer method, the pad for a transfer apparatus may include an upper pad which is connected to a body of the transfer apparatus and is made of a first material, and a lower pad which is fixed to a lower part of the upper pad so as to contact an object to be picked up and is made of a second material different from the first material. The second material may be more rigid compared with the first material.

This application claims priority from Korean Patent Application No. 10-2014-0086847 filed on Jul. 10, 2014 in the Korean Intellectual Property Office, the disclosure of which is incorporated herein by reference in its entirety.

### BACKGROUND

1. Technical Field

The present disclosure relates to a pad for a transfer apparatus, an object transfer apparatus including the pad, and an object transfer method.

2. Description of the Related Art

A transfer apparatus transfers a driver integrated circuit (IC) chip to a corresponding stage in each process of mounting the driver IC chip on a substrate. The transfer apparatus includes a transfer handler for picking up the driver IC chip. The transfer handler includes pick-up units, and the pick-up units pick up driver IC chips using a vacuum.

As products become lighter, thinner and more compact, even after the vacuum state of the transfer apparatus is removed, there is still a sticking phenomenon between the pick-up units of the transfer apparatus and the driver IC chips. The sticking phenomenon causes the driver IC chips to be placed incorrectly or turned over. Therefore, a sufficient time delay is required until the vacuum state of the transfer apparatus is completely removed. However, this time delay reduces an efficiency of a product manufacturing process.

### SUMMARY

Aspects of the present disclosure may provide a pad for a transfer apparatus. The pad may include two materials with different physical properties in order to prevent a sticking phenomenon between a pick-up unit and a product, and may absorb impact applied to the product in a pick-up and place operation.

Aspects of the present disclosure may also provide an object transfer apparatus including the pad.

Aspects of the present disclosure may also provide an object transfer method which can prevent a sticking phenomenon between a pick-up unit and a product, and may absorb impact applied to the product in a pick-up and place operation.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, there is provided a pad for a transfer apparatus. The pad may include an upper pad which is connected to a body of the transfer apparatus and is made of a first material, and a lower pad which is fixed to a lower part of the upper pad so as to contact an object to be picked up and is made of a second material different from the first material. The second material may be more rigid compared with the first material.

According to another aspect of the present disclosure, there is provided an object transfer apparatus. The object transfer apparatus may include a vacuum pad that includes an upper pad and a lower pad, and a body coupled to the vacuum pad. The upper pad may be made of a first material, and the lower pad may be made of a second material different from the first material. The second material may be more rigid compared with the first material. A through hole may be formed to penetrate through the upper pad and the lower pad.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a perspective view of a pad for a transfer apparatus according to an embodiment of the present disclosure;

FIG. 2 is a perspective view of the pad of FIG. 1 as seen from a different angle;

FIG. 3 is a cross-sectional view taken along the line A-A of FIG. 1 for explaining an operation of picking up a product;

FIG. 4 is a partial perspective view of an object transfer apparatus according to an embodiment of the present disclosure;

FIG. 5 is a cross-sectional view of the object transfer apparatus of FIG. 4 for explaining an operation of picking up a product;

FIG. 6 is a perspective view of a pad for a transfer apparatus according to another embodiment of the present disclosure;

FIG. 7 is a perspective view of a pad for a transfer apparatus according to another embodiment of the present disclosure;

FIG. 8 is a flowchart sequentially illustrating an object transfer method according to an embodiment of the present disclosure; and

FIG. 9 is a flowchart sequentially illustrating an object transfer method according to another embodiment of the present disclosure.

### DETAILED DESCRIPTION OF EMBODIMENTS

The present disclosure will now be described more fully hereinafter with reference to the accompanying drawings, in which preferred embodiments of the present disclosure are shown. The present disclosure may, however, be embodied in different forms and should not be construed as limited to the embodiments set forth herein. Rather, these embodiments are provided so that this disclosure will be thorough and complete, and will filly convey the scope of the present disclosure to those skilled in the art. The same reference numbers indicate the same components throughout the specification. In the attached figures, the thickness of layers and regions is exaggerated for clarity.

It will also be understood that when a layer is referred to as being “on” another layer or substrate, it can be directly on the other layer or substrate, or intervening layers may also be present. In contrast, when an element is referred to as being “directly on” another element, there are no intervening elements present.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the present disclosure (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

Unless defined otherwise, all technical and scientific terms used herein have the same meaning as commonly understood by one of ordinary skill in the art to which the present disclosure belongs. It is noted that the use of any and all examples, or exemplary terms provided herein is intended merely to better illuminate the present disclosure and is not a limitation on the scope of the present disclosure unless otherwise specified. Further, unless defined otherwise, all terms defined in generally used dictionaries may not be overly interpreted.

The present disclosure will be described with reference to perspective views, cross-sectional views, and/or plan views, in which preferred embodiments of the present disclosure are shown. Thus, the profile of an exemplary view may be modified according to manufacturing techniques and/or allowances. That is, the embodiments of the present disclosure are not intended to limit the scope of the present disclosure but cover all changes and modifications that can be caused due to a change in manufacturing process. Thus, regions shown in the drawings are illustrated in schematic form and the shapes of the regions are presented simply by way of illustration and not as a limitation.

A pad for a transfer apparatus to be described herein may include two materials with different physical properties and thus may utilize those advantages of both materials. That is, to prevent a sticking phenomenon between a pick-up unit and a product, a lower pad that contacts the product may be made of a rigid material. In addition, to absorb impact applied to the product, an upper pad connected to a body of the transfer apparatus may be made of a ductile material to have flexibility and elasticity.

Accordingly, it is possible to reduce the damage to the product in a pick-up and place operation for transferring the product. Furthermore, after the product is transferred, it can be quickly separated from the pad, thereby increasing a process efficiency.

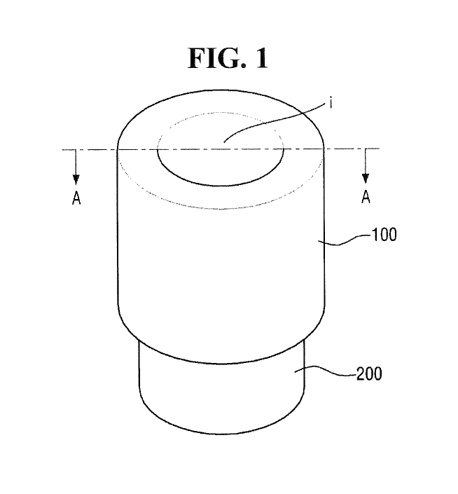

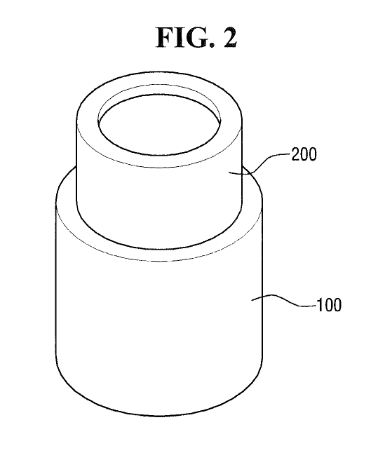

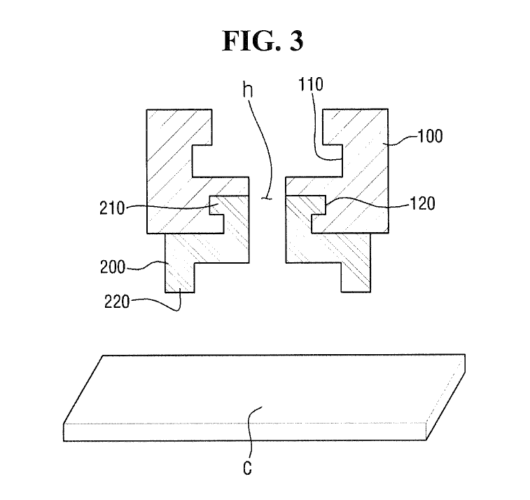

FIG. 1 is a perspective view of a pad for a transfer apparatus according to an embodiment of the present disclosure. FIG. 2 is a perspective view of the pad of FIG. 1 seen from a different angle. FIG. 3 is a cross-sectional view taken along the line A-A of FIG. 1 for explaining an operation of picking up a product.

Referring to FIGS. 1 through 3, the pad according to the current embodiment may include an upper pad 100 and a lower pad 200.

The upper pad 100 may be connected to a body of the transfer apparatus, and may be made of a first material m1. As illustrated in FIG. 1, an insertion portion i may be formed in the upper pad 100 such that the upper pad 100 can be coupled to a loader arm of the body of the transfer apparatus.

Specifically, referring to FIG. 3, a first groove 110 into which the loader arm can be inserted may be formed in the upper pad 100. Further, as will be described later, the lower pad 200 is coupled to the upper pad 100, and a second groove 120 into which a part of the lower pad 200 can be inserted may be formed in the upper pad 100.

In FIGS. 1 and 2, the upper pad 100 may be cylindrical, but the shape of the upper pad 100 is not limited to the cylindrical shape.

The lower pad 200 may be fixed to a lower part of the upper pad 100 so as to contact an object C to be picked up. The lower pad 200 may be made of a second material m2 different from the first material m1. Here, the second material m2 may be more rigid compared with the first material m1.

That is, the lower pad 200 may perform a pick-up and place operation by contacting the object C. The lower pad 200 may be made of a rigid material to be easily separated from the object C in the place operation and to prevent a sticking phenomenon. Therefore, the second material m2 that forms the lower pad 200 may be more rigid compared with the first material m1. For example, the second material m2 may include engineering plastic.

Engineering plastic has high heat resistance and mechanical strength. Examples of engineering plastic include polyamide resin, polyacetal, polycarbonate, polyethylene terephthalate, polybutylene terephthalate, denatured polyphenylene oxide, polyphenylene sulfide, polysulfone, polyamide-imide, polyaminobismaleimide, polyethersulfone, polyarylate, grafted polyphenylene ether, and polyether ether ketone (PEEK). In particular, PEEK may be applied in the present disclosure.

PEEK has good heat resistance and can be molded using a highly efficient molding method such as injection molding. Further, PEEK has high rigidity and excellent chemical resistance. In addition, PEEK has far higher water resistance, acid resistance, and alkali resistance than polyimide at high temperatures. While PEEK has a high molding temperature of 350 to 360° C., since its pyrolysis temperature is 560° C., it can be injection-molded and can be molded into a transparent film and a colored film.

On the other hand, the upper pad 100 may absorb impact applied to the object C in the pick-up and place operation. That is, the upper pad 100 may be made of the first material m1, which is more ductile compared with the second material m2, to have flexibility and elasticity. The first material m1 that forms the upper pad 100 may be more ductile compared with the second material m2 and may include, e.g., silicon.

However, the present disclosure is not limited thereto, and the first material m1 may include various rubbers. Specifically, the first material m1 may include natural rubber, derivatives (ebonite, chlorinated rubber, hydrochlorinated rubber, cyclorubber) of the natural rubber, butadiene synthetic rubber, olefin synthetic rubber, multi-sulfurized synthetic rubber, chlorosulfonated polyethylene, thermoplastic elastomer, etc.

Referring to FIG. 3, a first protrusion 210 which can be inserted into the second groove 120 of the upper pad 100 may be formed in the lower pad 200. That is, the upper pad 100 and the lower pad 200 can be coupled to or separated from each other.

A second protrusion 220 may be also formed in the lower pad 200 to contact the object C. A bottom surface of the lower pad 200 may be shaped like a doughnut. In particular, it is more advantageous when an area of the second protrusion 220 of the lower pad 200 which contacts the object C is smaller.

That is, in order for the object C to be readily separated from the lower pad 200 in the pick-up and place operation, the contact area between the object C and the lower pad 200 may be made small, and an area of the second protrusion 220 which contacts the object C may be made large enough only to pick up and transfer the object C when space inside the lower pad 200 is maintained in a vacuum state.

A through hole h may be formed to penetrate through the upper pad 100 and the lower pad 200, and air can pass through the through hole h. When the lower pad 200 contacts the object C, the space inside the upper pad 100 and the lower pad 200 may be maintained in the vacuum state to pick up the object C.

After the object C is picked up and transferred, the vacuum state may be released in the place operation in order to place the object C at a desired position. Here, the present disclosure may solve the sticking phenomenon between the lower pad 200 and the object C in this place operation.

An object transfer apparatus including the above-described pad will now be described.

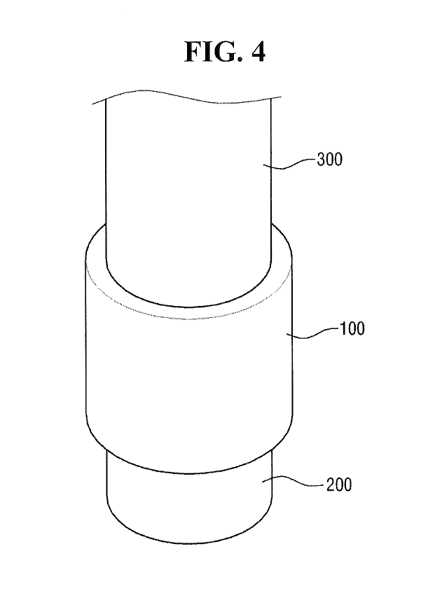

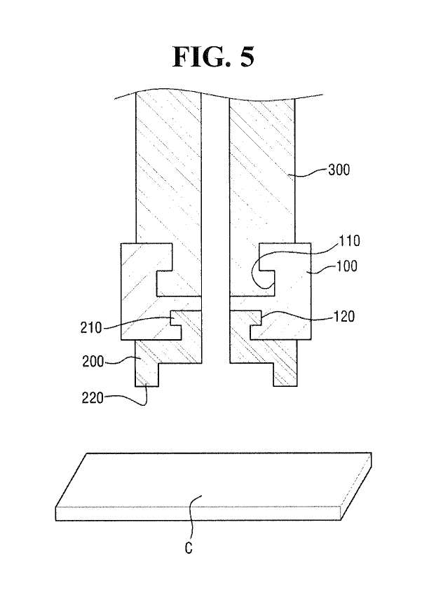

FIG. 4 is a partial perspective view of an object transfer apparatus according to an embodiment of the present disclosure. FIG. 5 is a cross-sectional view of the object transfer apparatus of FIG. 4 for explaining an operation of picking up a product. For simplicity, elements substantially identical to those of the pad according to the embodiment of FIGS. 1 through 3 will be omitted.

Referring to FIGS. 4 and 5, the object transfer apparatus according to the current embodiment may include a vacuum pad VP which includes an upper pad 100 and a lower pad 200, and may also include a body 300 to which the vacuum pad VP is coupled.

The upper pad 100 may be made of a first material m1, and the lower pad 200 may be made of a second material m2. The first material m1 and the second material m2 may be the same as those described above. For example, the first material m1 may include silicon, and the second material m2 may include engineering plastic.

The upper pad 100 and the lower pad 200 may be structured substantially as described above. That is, a first groove 110 into which part of the body 300 can be inserted may be formed in the upper pad 100, and a second groove 120 into which part of the lower pad 200 can be inserted may be formed in the lower pad 200.

A first protrusion 210 which can be inserted into the second groove 120 may be formed in the lower pad 200, and a second protrusion 220 may be formed in the lower pad 200 to contact an object C to be picked up.

In the above structure, a vertical cross section of the upper pad 100 may be hammer-shaped or ‘T’-shaped.

Pads for a transfer apparatus according to other embodiments of the present disclosure will now be described.

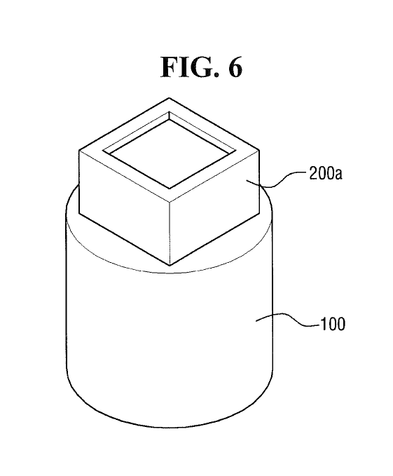

FIG. 6 is a perspective view of a pad for a transfer apparatus according to another embodiment of the present disclosure. For simplicity, elements substantially identical to those of the pad according to the embodiment of FIGS. 1 through 3 will be omitted.

Referring to FIG. 6, the pad according to the current embodiment may include an upper pad 100 and a lower pad 200a. A bottom surface of the lower pad 200a may have the cross-sectional shape of a quadrilateral, or other geometric object.

That is, a portion of the lower pad 200a which contacts an object C to be picked up may be quadrilateral. The area of an air passage may be greater when the bottom surface of the lower pad 200a is quadrilateral than when the bottom surface of the lower pad 200a is circular. Accordingly, this can increase an efficiency of a pick-up and place operation.

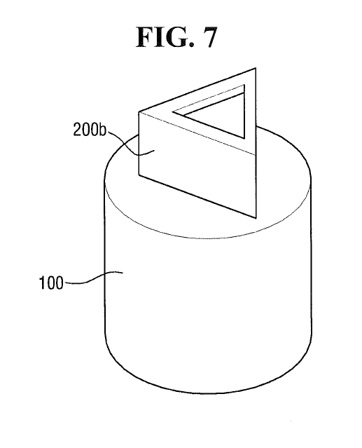

FIG. 7 is a perspective view of a pad for a transfer apparatus according to another embodiment of the present disclosure. For simplicity, elements substantially identical to those of the pad according to the embodiment of FIGS. 1 through 3 will be omitted.

Referring to FIG. 7, the pad according to the current embodiment may include an upper pad 100 and a lower pad 200b. A bottom surface of the lower pad 200b may have the cross-sectional shape of a triangle.

That is, a portion of the lower pad 200b which contacts an object C to be picked up may be triangular. When the bottom surface of the lower pad 200b is triangular, manufacturing costs can be reduced compared with when the bottom surface of the lower pad 200b is circular.

An object transfer method according to embodiments of the present disclosure will now be described.

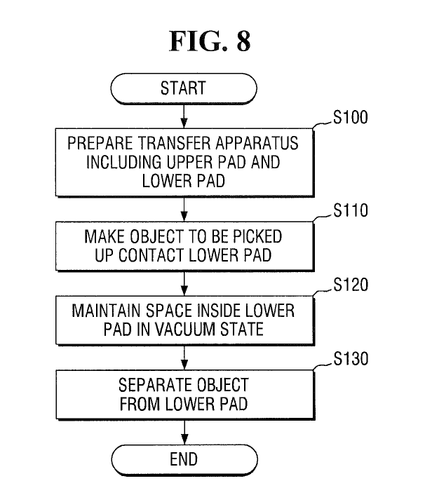

FIG. 8 is a flowchart sequentially illustrating an object transfer method according to an embodiment of the present disclosure.

Referring to FIG. 8, in the object transfer method according to the current embodiment, a transfer apparatus including a vacuum pad VP composed of an upper pad 100 and a lower pad 200 may be prepared (operation S100).

Here, the upper pad 100 and the lower pad 200 that constitute the vacuum pad VP may be identical to those according to the above-described embodiments of the present disclosure.

An object C to be picked up may be made to contact the lower pad 200 (operation S110). Here, since the upper pad 100 may be made of a ductile material, the upper pad 100 can absorb impact applied to the object C and prevent the object C from being damaged.

Space inside the lower pad 200 may be maintained in a vacuum state (operation S120). This is a process of sticking the object C and the lower pad 200 to each other for a pick-up and transfer operation. While the object C and the lower pad 200 remain stuck to each other in the vacuum state, they may be easily separated from each other when the vacuum state is released. As a result, process time may be reduced, and a process efficiency may be increased.

Therefore, in the present disclosure, the lower pad 20 may be made of a rigid material in order to solve the sticking phenomenon between the object C and the lower pad 200.

After the object C is transferred, air may be injected into the lower pad 200 in order to separate the object C from the lower pad 200 (operation S130). That is, the vacuum state of the space inside the lower pad 200 may be released to perform a place operation.

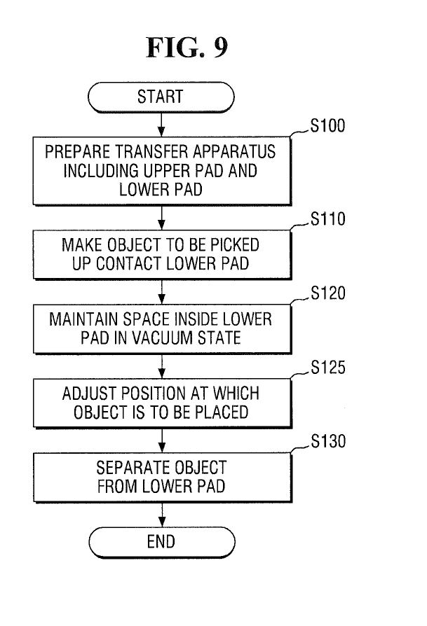

FIG. 9 is a flowchart sequentially illustrating an object transfer method according to another embodiment of the present disclosure. For simplicity, elements and features substantially identical to those of the object transfer method according to the embodiment of FIG. 8 will be omitted.

Referring to FIG. 9, in the object transfer method according to the current embodiment, a transfer apparatus including a vacuum pad VP composed of an upper pad 100 and a lower pad 200 may be prepared (operation S100). An object C to be picked up may be made to contact the lower pad 200 (operation S110). Space inside the lower pad 200 may be maintained in a vacuum state (operation S120).

Then, a position at which the object C is to be placed may be adjusted before the object C is separated from the lower pad 200 (operation S125). Here, since the upper pad 100 is made of a ductile material, the upper pad 100 may have flexibility. Therefore, it is possible to adjust the position at which the object C is to be placed without applying impact to the object C.

After the object C is transferred, air may be injected into the lower pad 200 in order to separate the object C from the lower pad 200 (operation S130). Here, the time required to separate the object C from the lower pad 200 may be 50 ms or less. That is, the lower pad 200 made of a rigid material may reduce the sticking phenomenon between the object C and the lower pad 200, and may perform a place operation for less than one tenth of the time required in the conventional art.

While the present disclosure has been particularly shown and described with reference to exemplary embodiments thereof, it will be understood by those of ordinary skill in the art that various changes in form and details may be made therein without departing from the spirit and scope of the present disclosure as defined by the following claims. It is therefore desired that the present embodiments be considered in all respects as illustrative and not restrictive, reference being made to the appended claims rather than the foregoing description to indicate the scope of the present disclosure.

What is claimed is:

1. A pad for a transfer apparatus, comprising:
an upper pad connected to a body of the transfer apparatus, the upper pad being made of a first material; and
a lower pad fixed to a lower part of the upper pad, the lower pad being configured to contact an object that is to be picked up, the lower pad being made of a second material that is different from the first material,
wherein the second material is more rigid than the first material.

2. The pad of claim 1, wherein the upper pad includes a first groove into which a part of the body of the transfer apparatus is inserted, and
the upper pad further includes a second groove into which a part of the lower pad is inserted.

3. The pad of claim 2, wherein the lower pad includes a first protrusion which is inserted into the second groove.

4. The pad of claim 3, wherein the lower pad includes a second protrusion which contacts the object to be picked up.

5. The pad of claim 1, wherein the first material is silicon.

6. The pad of claim 1, wherein the second material is engineering plastic.

7. The pad of claim 1, further comprising a through hole formed to penetrate through the upper pad and the lower pad.

8. The pad of claim 7, wherein air passes through the through hole.

9. The pad of claim 1, wherein a bottom surface of the lower pad is ring-shaped.

10. An object transfer apparatus comprising:
a vacuum pad comprising an upper pad and a lower pad; and
a body coupled to the vacuum pad,
wherein the upper pad is made of a first material,
the lower pad is made of a second material different from the first material, the second material being more rigid than the first material, and
the vacuum pad includes a through hole formed to penetrate through the upper pad and the lower pad.

11. The object transfer apparatus of claim 10, wherein the first material is silicon, and
the second material is engineering plastic.

12. The object transfer apparatus of claim 10, wherein the upper pad of the vacuum pad includes a first groove into which a part of the body is inserted, and
the upper pad further includes a second groove into which a part of the lower pad is inserted.

13. The object transfer apparatus of claim 12, wherein the lower pad includes a first protrusion which is inserted into the second groove.

14. The object transfer apparatus of claim 13, wherein the lower pad includes a second protrusion which contacts the object to be picked up.

15. The object transfer apparatus of claim 10, wherein a vertical cross section of the upper pad is T-shaped.

16. A method of transferring an object with a transfer apparatus that includes a vacuum pad having an upper pad, a lower pad, a through-hole formed to penetrate through the upper pad and the lower pad, the method comprising:
contacting an object to be picked up by the lower pad of the vacuum pad;
maintaining space inside the lower pad of the vacuum pad in a vacuum state;
adjusting a position at which the object is to be placed; and
separating the object from the lower pad of the vacuum pad by injecting air into the lower pad,
wherein the lower pad is more rigid than the upper pad.

17. The method of claim 16, wherein the air passes through the through-hole.

18. The method of claim 16, wherein a time required to separate the object from the lower pad is 50 ms or less.

19. The method of claim 16, wherein the lower pad is fixed to a lower part of the upper pad.

20. The method of claim 16, wherein the upper pad is cylindrical, and
the lower pad is cylindrical, is of a triangular cross-section, or is of a quadrilateral cross-section.
